(19) United States
(12) Patent Application Publication
(10) Pub. No.: US 2011/0140168 A1
(43) Pub. Date: Jun. 16, 2011

(54) AVALANCHE PHOTOTECTOR WITH INTEGRATED MICRO LENS

(75) Inventors: Jae-Sik SIM, Daejeon (KR); Bongki Mheen, Daejeon (KR); Myungsook Oh, Daejeon (KR); Yong-Hwan Kwon, Daejeon (KR); Eun Soo Nam, Daejeon (KR)

(73) Assignee: ELECTRONICS AND TELECOMMUNICATIONS RESEARCH INSTITUTE, Daejeon (KR)

(21) Appl. No.: 12/769,198

(22) Filed: Apr. 28, 2010

(30) Foreign Application Priority Data
Dec. 15, 2009 (KR) 10-2009-0124863

(51) Int. Cl. H01L 31/107

(52) U.S. Cl. 257/186; 257/E31.064

(57) ABSTRACT

Provided is an avalanche photodetector with an integrated micro lens. The avalanche photodetector includes a light absorbing layer on a semiconductor substrate, an amplification layer on the light absorbing layer, a diffusion layer within the amplification layer, and the micro lens disposed corresponding to the diffusion layer. The micro lens includes a first refractive layer and a second refractive layer having a refractive index less than that of the first refractive layer.

### CROSS-REFERENCE TO RELATED APPLICATIONS

This U.S. non-provisional patent application claims priority under 35 U.S.C. §119 of Korean Patent Application No. 10-2009-0124863, filed on Dec. 15, 2009, the entire contents of which are hereby incorporated by reference.

### BACKGROUND OF THE INVENTION

The present invention disclosed herein relates to a photodetector, and more particularly, to an avalanche photodetector that can improve light receiving efficiency.

As demand of a high-speed large-capacity optical communication system and an image processing system increases, researches with respect to a photodetector that is necessary for the systems are actively conducted in recent years.

The photodetector irradiates light onto an object and detects the light reflected or scattered from the object through a spherical lens. Light incident into the photodetector is converted into an electrical signal through a photodiode and is transmitted to an optical receiver through an amplifier.

A P-type intrinsic N-type photodiode (PIN-PD) having a simple structure may be used as the photodiode. However, since the PIN-PD does not have an internal gain, the PIN-PD has a poor sensitivity. Alternatively, when an avalanche photodiode (APD) is used as the photodiode, since the APD has an internal amplification function, the sensitivity may be improved.

Although light is incident into an entire region of the photodetector, the light incident into a region (e.g., a logic region) in which a light receiving function is not provided may not be converted into an electrical signal. Thus, the light incident into in which a light receiving function may be lost. As a result, the sensitivity of the photodetector may be deteriorated. Thus, to reduce the light loss, it is necessary to increase an area of the photodiode.

However, the photodetector includes the photodiode that converts light into an electrical signal as well as the logic region in which control circuits that datarates the electrical signal transmitted from the photodiode are disposed. Thus, increase of an area of a light receiving region is limited because of an area occupied by the logic region. Thus, required is a photodetector that can reduce a loss of light incident into the photodetector without increasing the area of the light receiving region.

### SUMMARY OF THE INVENTION

The present invention provides an avalanche photodetector having improved light receiving efficiency.

The object of the present invention is not limited to the aforesaid, but other objects not described herein will be clearly understood by those skilled in the art from descriptions below.

Embodiments of the present invention provide avalanche photodetectors including: a light absorbing layer on a semiconductor substrate; an amplification layer on the light absorbing layer; a diffusion layer within the amplification layer; and the micro lens disposed corresponding to the diffusion layer, wherein the micro lens includes a first refractive layer and a second refractive layer having a refractive index less than that of the first refractive layer.

Details of other exemplary embodiments are included in detailed description and drawings.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a sectional view of an avalanche photodetector according to an embodiment of the present invention;

FIG. 2 is a sectional view of an avalanche photodetector according to another embodiment of the present invention; and

FIGS. 3 to 6 are views illustrating a process of manufacturing an avalanche photodetector according to an embodiment of the present invention.

### DETAILED DESCRIPTION OF PREFERRED EMBODIMENTS

Objects, other objects, characteristics and advantages of the present invention will be easily understood from an explanation of a preferred embodiment that will be described in detail below by reference to the attached drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art Like reference numerals refer to like elements throughout.

In the following description, the technical terms are used only for explain a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the embodiment in the detailed description will be described with sectional views as ideal exemplary views of the present invention. In the specification, it will be understood that when a layer (or film) is referred to as being ‘on’ another layer or substrate, it can be directly on the other layer or substrate, or intervening layers may also be present. Also, in the figures, the dimensions of layers and regions are exaggerated for clarity of illustration. Thus, areas exemplified in the drawings have general properties, and are used to illustrate a specific shape of a semiconductor package region. Thus, this should not be construed as limited to the scope of the present invention.

Hereinafter, an avalanche photodetector according to embodiments of the present invention will be described in detail with reference to accompanying drawings.

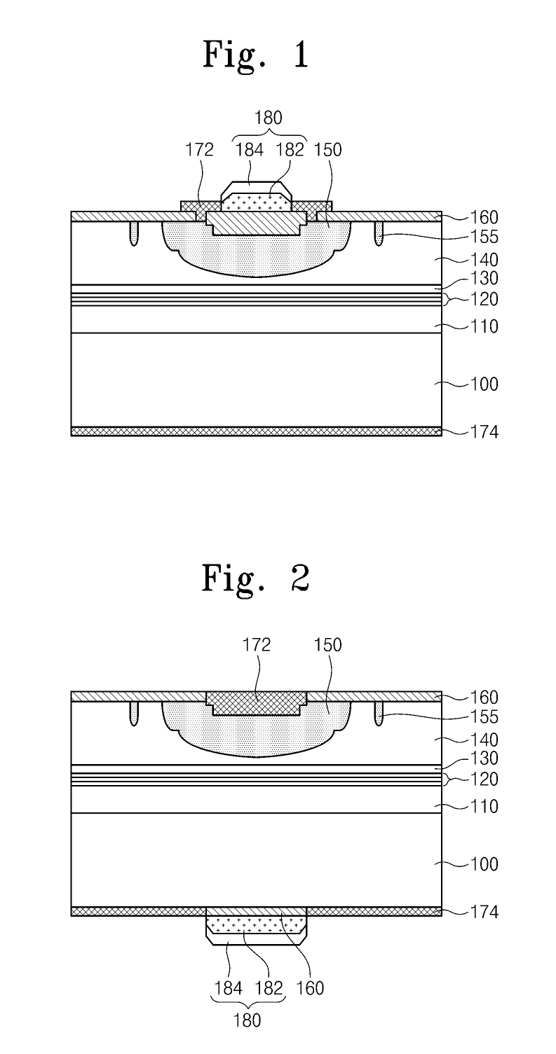

FIG. 1 is a sectional view of an avalanche photodetector according to an embodiment of the present invention.

Referring to FIG. 1, an avalanche photodetector according to an embodiment of the present invention may be a front side incident type photodetector in which light is incident onto a front side of a semiconductor substrate 100.

The avalanche photodetector includes the semiconductor substrate 100, a light absorbing layer 110, a grading layer 120, an electric field buffer layer 130, an amplification layer 140, a diffusion layer 150, a passivation layer 160, an upper electrode 172, a lower electrode 174, and a micro lens 180.

An n+-InP substrate may be used as the semiconductor substrate 100. An n-InP buffer layer (not shown), the n-InGaAsP light absorbing layer 110, the n-InGaAsP grading layer 120 including a plurality of layers having band gaps different from each other, the n-InP electric field buffer layer 130, and the n-InP amplification layer 140 may be sequentially stacked on the semiconductor substrate 100. Also, the p⁺InP diffusion layer 150 is disposed within the amplification layer 140 to form a spatially limited PN junction.

A profile of the diffusion layer 150 may be formed as illustrated in FIG. 1 to prevent an electric field from be concentrated into an edge of the diffusion layer 150. That is, the diffusion layer 150 may have a central portion deeper than an edge portion thereof.

A guard ring 155 having the same conductivity as the diffusion layer 150 may be disposed within the amplification layer 140. The guard ring 155 may be spaced from a circumference of the diffusion layer 150 and have a ring shape. Also, the guard ring 155 may be electrically isolated from the diffusion layer 150. The guard ring 155 may prevent avalanche breakdown phenomenon from firstly occurring at an edge portion than a central portion of the PN junction due to the concentration of the electric field into the edge portion of the diffusion layer 150.

The plurality of layers constituting the grading layer 120 may have the band gaps between the semiconductor substrate 100 and the light absorbing layer 110. The n-InP electric field buffer layer 130 may have an impurity concentration of about 3.0×10¹⁷ to about 3.45×10¹⁷. The n-InP amplification layer 140 may have a thickness of about 3.5 μm to about 4.5 μm.

The passivation layer 160 formed of silicon nitride (SiNₓ) is disposed on surfaces of the amplification layer 140 and the diffusion layer 150.

The upper electrode 172 and the lower electrode 174 are disposed on upper and lower portions of the avalanche photodetector. The upper electrode 172 is connected to the diffusion layer 150, and the lower electrode layer 174 is connected to the semiconductor substrate 100. Also, the upper electrode 172 may pass through the passivation layer 160 and then be connected to the diffusion layer 150. Also, all of the upper and lower electrodes 172 and 174 may be disposed on the passivation layer 160 disposed above the semiconductor substrate 100 or disposed on a back surface of the semiconductor substrate 100.

The micro lens 180 for collecting light is integrally disposed above the diffusion layer 150. Specifically, the micro lens 180 may be disposed on a top surface of the passivation layer 160 covering a surface of the diffusion layer 150. Also, the micro lens 180 may be disposed between the upper electrodes 172 connected to the diffusion layer 150. The micro lens 180 may have a central portion thicker than an edge portion thereof. That is, as illustrated in FIG. 1, the micro lens 180 may have a flat top surface at the central portion thereof and an inclined surface at the edge portion thereof. Also, the micro lens 180 may have a substantially convex spherical surface to improve light collection efficiency.

The micro lens 180 may have a structure in which a first refractive layer 182 and a second refractive layer 184 having a refractive index less than that of the first refractive layer 182 are stacked. The first refractive layer 182 and the second refractive layer 184 may be sequentially stacked on the passivation layer 160. The first refractive layer 182 may be formed of a material having a refractive index of about 2.0 to about 2.5. The second refractive layer 184 may be formed of a material having a refractive index of about 1.4 to about 1.6. For example, the first refractive layer 184 may be formed of at least one of TiO₂, ZrO₂, HfO₂, SrTiO₃, BaTiO₃, PZT, and PLZT. The second refractive layer 184 may be formed of at least one of SiO₂, SiON, and SiNₓ. Specifically, the first refractive layer 182 may be formed of TiO₂, and the second refractive layer 184 may be formed of SiO₂.

The micro lens 180 integrally disposed on the photodetector changes an incident path of light incident into a region except a photodiode to concentrate the light into the diffusion layer 150. Thus, light receiving efficiency of the avalanche photodetector may be improved. Also, since the micro lens 180 has the structure in which the refractive layers 182 and 184 having the different refractive indexes are stacked, the light collection efficiency may be further improved.

When light is incident into the avalanche photodetector, photoelectrons within the light absorbing layer 110 are excited to generate electron hole pairs. The electron hole pairs generated in the light absorbing layer 110 may be separated by a strong electric field. The separated holes may be quickly injected into the amplification layer 140 through the grading layer 120, and the separated electrons may be emitted through the lower electrode 174. The holes injected into the amplification layer 140 may be accelerated by the strong electric field of the amplification layer 140. The accelerated holes may be impact-ionized, and the ionized holes may generate additional holes. That is, holes may be additionally generated by the large electric field of the amplification layer 140 to amplify optical current.

The avalanche photodetector may internally amplify an electrical signal into which the incident light is converted to output an electrical signal having a relatively large signal-to-noise ratio (SNR).

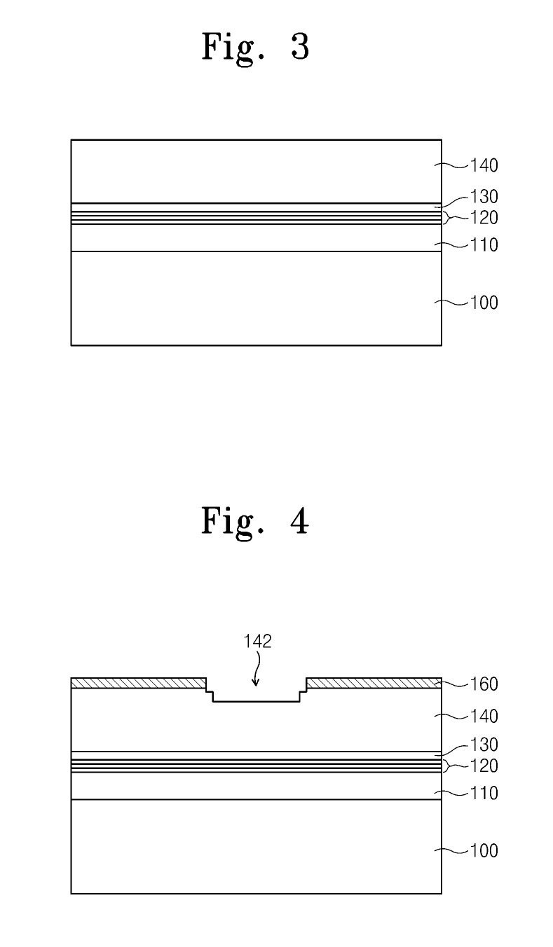

FIG. 2 is a sectional view of an avalanche photodetector according to another embodiment of the present invention.

Referring to FIG. 2, an avalanche photodetector according to another embodiment of the present invention may be a back side incident type photodetector in which light is incident onto a back side of a semiconductor substrate 100.

The avalanche photodetector according to another embodiment of the present invention may have substantially the same structure as the previously described front side incident type photodetector in which the light is incident onto the front side of the semiconductor substrate 100. That is, an n-InP buffer layer (not shown), an n-InGaAsP light absorbing layer 110, an n-InGaAsP grading layer 120 including a plurality of layers having band gaps different from each other, an n-InP electric field buffer layer 130, and an n-InP amplification layer 140 may be sequentially stacked on the semiconductor substrate 100. Also, a p⁺InP diffusion layer 150 is disposed within the amplification layer 140 to form a spatially limited PN junction. A distance between the diffusion layer 150 and the electric field buffer layer 130 may be much larger at an edge portion than at a central portion in the diffusion layer 150.

Also, a guard ring 155 having the same conductivity as the diffusion layer 150 may be disposed within the amplification layer 140. The guard ring 155 may be disposed in a ring shape along a circumference of the diffusion layer 150. Also, the guard ring 155 may be electrically isolated from the diffusion layer 150.

A passivation layer 160 formed of silicon nitride (SiNₓ) is disposed on surfaces of the amplification layer 140 and the diffusion layer 150.

Also, an upper electrode 172 and a lower electrode 174 are disposed on upper and lower portions of the avalanche photodetector. The upper electrode 172 is connected to the diffusion layer 150, and the lower electrode layer 174 is connected to the semiconductor substrate 100. Also, the upper electrode 172 may pass through the passivation layer 160 and then be connected to the diffusion layer 150. The lower electrode 173 may be directly connected to a back surface of the semiconductor substrate 100.

According to another embodiment of the present invention, the upper electrode 172 may be buried in the passivation layer 160 while it contacts the diffusion layer 150. That is, the avalanche photodetector may have a flat top surface. Also, the avalanche photodetector may be disposed on the back surface of the semiconductor substrate 100 except a region corresponding to the diffusion layer 150. The passivation layer 160 formed of silicon nitride may be disposed on the back surface of the semiconductor substrate 100 in a region corresponding to the diffusion layer 150.

According to another embodiment of the present invention, a micro lens 180 is integrally disposed below the semiconductor substrate 100 corresponding to the diffusion layer 150. Specifically, the micro lens 180 may be disposed on the passivation layer 160 disposed on the back surface of the semiconductor substrate 100. The micro lens 180 may have a central portion thicker than an edge portion thereof. That is, as illustrated in FIG. 2, the micro lens 180 may have a flat top surface at the central portion thereof and an inclined surface at the edge portion thereof. Also, the micro lens 180 may have a substantially convex spherical surface to improve light collection efficiency.

Like an embodiment of the present invention, the micro lens 180 may have a structure in which a first refractive layer 182 and a second refractive layer 184 having a refractive index less than that of the first refractive layer 182 are stacked. That is, the first refractive layer 182 and the second refractive layer 184 may be sequentially stacked on the passivation layer 160. The first refractive layer 182 may be formed of a material having a refractive index of about 2.0 to about 2.5. The second refractive layer 184 may be formed of a material having a refractive index of about 1.4 to about 1.6. For example, the first refractive layer 184 may be formed of at least one of TiO₂, ZrO₂, HfO₂, SrTiO₃, BaTiO₃, PZT, and PLZT. The second refractive layer 184 may be formed of at least one of SiO₂, SiON, and SiNₓ. Specifically, the first refractive layer 182 may be formed of TiO₂, and the second refractive layer 184 may be formed of SiO₂.

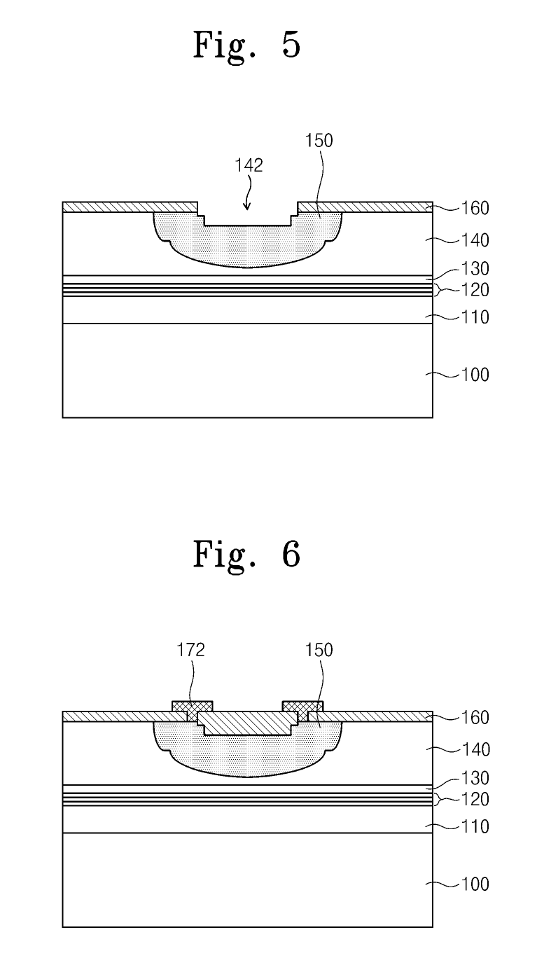

FIGS. 3 to 6 are views illustrating a process of manufacturing an avalanche photodetector according to an embodiment of the present invention.

Referring to FIG. 3, a metal-organic chemical vapor deposition (MOCVD) process or a molecular beam epitaxy (MBE) process is performed to sequentially form an n-InP buffer layer (not shown), an n-InGaAsP light absorbing layer 110, an n-InGaAsP grading layer 120, an n-InP electric field buffer layer 130, and an n-InP amplification layer 140 on an n⁺InP substrate 11.

Here, the grading layer 120 may include one layer having a band gap which has an intermediate value between a band gap of InP and that of InGaAs or a plurality of layers having band gaps different from each other. N-type impurities may be or may not be doped into the grading layer 120. The electric field buffer layer 130 may have an impurity concentration of about 3.0×10¹⁷ to about 3.45×10¹⁷. The amplification layer 140 may have a thickness of about 3.5 μm to about 4.5 μm.

Referring to FIG. 4, an etch region 142 for forming a PN junction is formed in the amplification layer 140. Specifically, a passivation layer 160 is formed on the amplification layer 140 using an insulation material such as SiNₓ. The passivation layer 160 is patterned to expose the amplification layer 140 in the region in which the PN junction will be formed. Then, the amplification layer 140 is etched by a predetermined depth using the patterned passivation layer 160 to form the etch region 142. The etch region 142 may have an etch depth of about 100 nm to about 200 nm. A depth of the PN junction may be adjusted according to the depth of the etch region 142. According to an embodiment, the etch region 142 may have the etch depths different from each other at a central portion and an edge portion thereof.

Referring to FIG. 5, after the etch region 142 is formed, impurities are diffused through the etch region 142 to form a p⁺InP diffusion layer 150.

Specifically, a deposition process is performed to sequentially form an impurity diffusion layer (not shown) formed of a material having a diffusion coefficient different from that of the amplification layer 140 and an insulation layer (not shown) in the etch region 142. At this time, the impurity diffusion layer may include a layer containing impurities such as zinc (Zn) or cadmium (Cd), and the insulation layer may include a silicon oxide layer.

Thereafter, a thermal processing is performed on the resultant at a temperature of about 400° C. to about 550° C. for about 10 minutes to about 30 minutes. As a result, P-type impurities may be diffused into the n-InP amplification layer 140 to form the p⁺InP diffusion layer 150.

The diffusion layer 150 may be variously adjusted in size and depth at the central portion and the edge portion thereof according to a size, a thickness, and a position of the impurity diffusion layer for forming the diffusion layer 150. According to an embodiment of the present invention, since the etch region 142 has the different depths at the central and edge portions, the impurities may be diffused into different depths when the diffusion layer 150 is formed. Thus, a distance between the diffusion layer 150 and the electric field buffer layer 130 may be larger at the edge portion than at the central portion in the diffusion layer 150.

Thereafter, the impurity diffusion layer and the insulation layer may in the etch region 142 be removed. Also, a silicon oxide layer may be deposited again in the etch region 142, and then a thermal processing may be performed to stabilize the impurities (i.e., Zn or Cd) in the diffusion layer 150. At this time, the thermal processing may be performed at a temperature of about 400° C. to about 550° C. for about 10 minutes to about 30 minutes.

As shown in FIG. 1, when the diffusion layer 150 is formed, a guard ring (see reference numeral 155 of FIG. 1) may be formed also along a circumference of the diffusion layer 150. That is, a surface of the amplification layer 140 on which the guard ring (see reference numeral 155 of FIG. 1) will be formed is exposed, and then the impurity diffusion layer may be deposited on the exposed surface of the amplification layer 140. Then, a thermal processing may be performed to form the diffusion layer 150 as well as the guard ring (see reference numeral 155 of FIG. 1).

Referring to FIG. 6, an upper electrode 172 connected to the diffusion layer 150 and a lower electrode 174 connected to the semiconductor substrate 100 are formed.

Specifically, before the upper and lower electrodes 172 and 174 are formed, the passivation layer 160 is formed in the etch region 142, and then, a top surface of the passivation layer 160 is planarized. As a result, the passivation layer 160 may be formed on the entire surface of the amplification layer 140 and the diffusion layer 150. Here, the passivation layer may include a silicon nitride layer. The silicon nitride layer may be used as an anti-reflective layer that prevents light incident into the photodetector from being reflected.

The passivation layer 160 is patterned to form a contact region exposing a surface of the diffusion layer 150 at a predetermined region. A conductive metal layer is deposited in the contact region and then patterned to form the upper electrodes 172.

Thereafter, a back surface of the semiconductor substrate 100 is polished to reduce a thickness of the semiconductor substrate 100. A conductive metal layer is deposited on the polished back surface of the semiconductor substrate 100 and then patterned to form the lower electrodes 174. A Zn—Au alloy, Au, or a Ti/Pt/Au alloy may be used as the metal layer forming the upper and lower electrodes 172 and 174.

The upper and lower electrodes 172 and 174 may have different shapes according to a direction in which light is incident. For example, as shown in FIG. 1, in case of the front side incident type photodetector, the upper electrodes 172 may be connected to a circumference of the central portion of the diffusion layer 150, and the lower electrodes 174 may cover the back surface of the semiconductor substrate 100. As shown in FIG. 2, in case of the back side of a semiconductor substrate 100, the upper electrodes 172 may be formed at the central portion of the diffusion layer 150, and the lower electrodes 174 may be formed on the back surface of the semiconductor substrate 100 except a region corresponding to the diffusion layer 150. Also, in the back side of a semiconductor substrate 100, the silicon nitride layer serving as the anti-reflective layer for preventing the light incident into the photodetector from being reflected may be formed on the back surface of the semiconductor substrate 100 corresponding to the diffusion layer 150.

A micro lens 180 is formed on the top or back surface of the semiconductor substrate 100 corresponding to the diffusion layer.

Specifically, as shown in FIG. 1, in case of the front side incident type photodetector, the micro lens 180 is formed on the passivation layer 160 adjacent to the surface of the diffusion layer 150.

A first refractive layer 182 and a second refractive layer 184 having a refractive index less than that of the first refractive layer 182 may be sequentially deposited on the passivation layer 160. Then, a dry etching process such as a reactive ion etching (RIE) may be performed to form the micro lens 180.

The first refractive layer 182 may be formed of a material having a refractive index of about 2.0 to about 2.5. The second refractive layer 184 may be formed of a material having a refractive index of about 1.4 to about 1.6. For example, the first refractive layer 184 may be formed of at least one of TiO₂, ZrO₂, HfO₂, SrTiO₃, BaTiO₃, PZT, and PLZT. The second refractive layer 184 may be formed of at least one of SiO₂, SiON, and SiNₓ.

Also, the dry etching process may be performed to form the micro lens 180 having an oval shape. That is, the micro lens 180 may have a central portion thicker than an edge portion thereof.

As shown in FIG. 2, in case of the back side incident type photodetector, the first and second refractive layers 182 and 184 may be sequentially stacked on the back surface of the semiconductor substrate 100 corresponding to the diffusion layer 150 and then patterned to form the micro lens 180.

According to the avalanche photodetector of the prevent invention, the micro lens can be disposed on the upper and lower portions of the photodetector to improve the light receiving efficiency of the photodetector. Also, the micro lens can be formed using the refractive layers having the refractive indexes different from each other to further improve the light collection efficiency of the incident light.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An avalanche photodetector comprising:
a light absorbing layer on a semiconductor substrate;
an amplification layer on the light absorbing layer;
a diffusion layer within the amplification layer; and
a micro lens disposed corresponding to the diffusion layer,
wherein the micro lens comprises a first refractive layer and a second refractive layer having a refractive index less than that of the first refractive layer.

2. The avalanche photodetector of claim 1, wherein the first refractive layer is disposed adjacent to the diffusion layer, and the second refractive layer is disposed on the first refractive layer.

3. The avalanche photodetector of claim 1, wherein the first refractive layer is formed of at least one of TiO2, ZrO2, HfO2, SrTiO3, BaTiO3, PZT, and PLZT.

4. The avalanche photodetector of claim 1, wherein the second refractive layer is formed of at least one of SiO2, SiON, and SiNx.

5. The avalanche photodetector of claim 1, wherein the micro lens has a central portion thicker than an edge portion thereof.

6. The avalanche photodetector of claim 1, wherein the semiconductor substrate has a first surface and a second surface opposite to the first surface,
the diffusion layer is disposed adjacent to the first surface of the semiconductor substrate, and
the micro lens is disposed on the first surface of the semiconductor substrate.

7. The avalanche photodetector of claim 1, wherein the semiconductor substrate has a first surface and a second surface opposite to the first surface,
the diffusion layer is disposed adjacent to the first surface of the semiconductor substrate, and
the micro lens is disposed on the second surface of the semiconductor substrate.

8. The avalanche photodetector of claim 1, further comprising an upper electrode connected to the diffusion layer and a lower electrode connected to the semiconductor substrate.

9. The avalanche photodetector of claim 1, further comprising a guard ring spaced from a circumference of the diffusion layer and having the same conductivity as the diffusion layer.

10. The avalanche photodetector of claim 1, further comprising:
a grading layer comprising a plurality of layers having band gaps different from each other between the light absorbing layer and the amplification layer; and
an electric field buffer layer disposed between the grading layer and the amplification layer.

11. The avalanche photodetector of claim 1, further comprising a passivation layer covering surfaces of the amplification layer and the diffusion layer.

12. The avalanche photodetector of claim 11, wherein the micro lens is disposed on the passivation layer.

13. The avalanche photodetector of claim 1, wherein a distance between an edge portion of the diffusion layer and the electric field buffer layer is greater than that between a central portion of the diffusion layer and the light absorbing layer.

14. The avalanche photodetector of claim 1, wherein the semiconductor layer comprises an InP substrate, the light absorbing layer is formed of InGaAsP, and the amplification layer is formed of InP.

15. The avalanche photodetector of claim 1, wherein the semiconductor substrate, the light absorbing layer, and the amplification layer are an N-type, and the diffusion layer is a P-type.
